(19) United States
(12) Patent Application Publication
(10) Pub. No.: US 2008/0186690 A1
(43) Pub. Date: Aug. 7, 2008

(54) Electronics Package And Manufacturing Method Thereof

(75) Inventors: Jani Miettinen, Hyvinkaa (FI); Pauliina Mansikkamaki, Hameenkyro (FI); Petri Molkkari, Tampere (FI); Matti Mantysalo, Tampere (FI); Jani Valtanen, Tampere (FI)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Nokia Corporation, Espoo (FI)

(21) Appl. No.: 11/672,352

(22) Filed: Feb. 7, 2007

(51) Int. Cl. H05K 1/18; H05K 3/30

(52) U.S. Cl. 361/761; 29/830; 29/841

(57) ABSTRACT

A method for manufacturing an electronics package is provided that comprises forming at least one module block by providing a carrier substrate having a recess, placing at least one electronic component die in said recess, filling said recess with a molding material, and depositing a circuit layer connected with said at least one component die. It further provides an electronics package, comprising a carrier substrate having a recess, at least one electronic component die placed in said recess, a molding material filling said recess, and a circuit layer connected with said at least one component die.

The invention relates in general to printed electronics, microelectronics packaging, integration and miniaturization of electronics. It is particularly concerned with an electronics package and the manufacturing method thereof.

### PRIOR ART

Usually electronics components are packaged, but the active die area inside a package can be as low as 10% of the overall package size. Electronics packages are therefore big in relation to their active area, as well as having a large volume and also a high weight.

Prior art electronics modules use substrates that are made using conventional printed wiring board (PWB) techniques, or using ceramic substrates. Components are attached using surface-mount technology (SMT), flip chip, tape automated bonding (TAB) or wire bonding. These processes are material consuming and their related time to market is considerably long.

### SUMMARY OF THE INVENTION

The invention enables electronics miniaturization, i.e. less weight, less volume, smaller size, as well as having more functions, reduced manufacturing costs and a shorter time to market. It enables manufacturing of stacked, light-weight, high-performance multi-functional modules with low costs.

According to a first aspect a method for manufacturing an electronics package is provided, comprising:
forming at least one module block, comprising
providing a carrier substrate comprising a recess;
placing at least one electronic component die in said recess;
filling said recess with a molding material; and
depositing a circuit layer connected with said at least one component die.

Electronics packages or modules, respectively, that are made possible by the invention are small compared to conventional ways of assembling components. The modules are stackable. This also enables smaller and lighter products, with more functionality. Another advantage relates to modularity, because with the invention the same carrier can be used in several different products, which allows to lower costs. Using inkjet printed wirings provides more flexibility to the manufacturing process. In this manner design changes can be made easily. Inkjet printing process additionally minimizes the amount of waste materials. The invention is, however, not limited to using inkjet printing techniques, but also includes using other methods to form the wirings such as single head microdepositers (as maskless mesoscale material deposition M3D and solvent ink jet SIJ).

According to an exemplary embodiment said recess comprises a through-hole, and said placing step comprises placing said at least one electronic component in said through-hole at level with said carrier substrate. The components are placed in said through-hole before filling the through-hole with molding material. Components can be attached in this manner, or can in other embodiments also be attached prior to filling with molding material, e.g. by attaching the component(s) to the side walls of the through-hole using adhesives or force-fit. An advantage of this through-hole embodiment is the possibility to further reduce the thickness of the electronics package.

According to an exemplary embodiment said circuit layer comprises conductive and dielectric materials.

According to an exemplary embodiment said at least one component die is attached to the bottom of said recess.

According to an exemplary embodiment the method further comprises:
forming at least one via in said carrier substrate.

Through-Vias allow to provide electrical paths between a plurality of stacked modules, e.g. from the bottom module to the top module, through one or more other (intermediate) modules. The vias can be implemented using microvias or plated-through-holes.

According to an exemplary embodiment the method further comprises:
attaching at least one electronic component to said circuit pattern.

This embodiment allows attaching e.g. standard SMD devices on top of a module. If the respective module is the topmost module there are no restrictions to the height of attached devices. In case the module is an intermediate module in a stack the height is restricted by the available vertical space between modules.

According to an exemplary embodiment said carrier substrate is provided with an internal wiring and said circuit layer is deposited such that it also connects said internal wiring.

According to an exemplary embodiment the method further comprises:
forming at least one interconnection terminal.

Interconnection terminals are connectors provided on the upper and/or lower face of a module, to make contact with other (stacked) modules, or with e.g. a printed wiring board. According to the invention an interconnection array can be provided that is SMT compatible, thus allowing to be used in conjunction with standard SMT devices.

According to an exemplary embodiment said at least one interconnection terminal is formed in the area of said recess. In this manner more connections can be made between stacked layers and also the electrical paths can be kept shorter.

According to an exemplary embodiment at least two module blocks are formed, and the method further comprises:
stacking said at least two module blocks on top of each other, wherein said at least one interconnection terminal electrically connects said at least two module blocks.

According to an exemplary embodiment the method further comprises:
depositing a second circuit layer on said carrier substrate on the side opposite to said recess, said second circuit structure being connected with said at least one via.

This embodiment allows e.g. to provide a printed antenna structure or other circuit structure in the inventive module.

According to an exemplary embodiment said carrier substrate is provided with an electromagnetic shielding layer.

This embodiment is particularly advantageous in connection with the previous embodiment, as an antenna of an RF circuit/device usually requires electromagnetic shielding.

According to another aspect a computer-readable medium is provided, storing instructions for instructing a computer to perform the steps of the method described above when run on said computer.

According to still another aspect of the present invention an electronics package is provided, comprising:
a carrier substrate comprising a recess;
at least one component die placed in said recess;
a molding material filling said recess; and
a circuit layer connected with said at least one component die.

According to an exemplary embodiment said recess comprises a through-hole, and said at least one electronic component is placed in said through-hole at level with said carrier substrate. The component is held in place either by the molding material, or in other embodiments also by adhesives attaching it to the through-hole's side walls or by force-fit within said through-hole.

According to an exemplary embodiment said circuit layer comprises conductive and dielectric materials.

According to an exemplary embodiment said at least one component die is attached to the bottom of said recess.

According to an exemplary embodiment the electronics package further comprises:
at least one via in said carrier substrate.

According to an exemplary embodiment the electronics package further comprises:
at least one electronic component attached to said circuit pattern.

According to an exemplary embodiment said carrier substrate further comprises an internal wiring, and wherein said circuit layer connects with said internal wiring.

According to an exemplary embodiment the electronics package further comprises:
at least one interconnection terminal.

According to an exemplary embodiment said at least one interconnection terminal is located in the area of said recess.

According to an exemplary embodiment the electronics package comprises at least two module blocks stacked on top of each other, wherein said at least one interconnection terminal electrically connects said at least two module blocks.

According to an exemplary embodiment the electronics package further comprises:
a second circuit layer on said carrier substrate on the side opposite to said recess, said second circuit structure being connected with said at least one via.

According to an exemplary embodiment the electronics package further comprises:
an electromagnetic shielding layer.

### BRIEF DESCRIPTION OF THE DRAWINGS

The invention can be more fully understood by the following detailed description of exemplary embodiments, when also referring to the drawings which are provided in an exemplary manner only and are not intended to limit the invention to any particular embodiment illustrated therein. In the drawings

FIG. 1 shows a cross section of an electronics package according to an embodiment of the invention;

FIG. 2 shows a cross section of an electronics package according to an alternative embodiment of the invention;

FIG. 3 shows a cross section of a stacked electronics package according to an embodiment of the invention;

FIG. 4 shows a cross section of an electronics package according to another embodiment of the invention; and

FIG. 5 is a flow diagram showing steps of an embodiment of the method of the invention.

### DETAILED DESCRIPTION OF THE INVENTION

The invention enables a miniaturization of electronics packages using bare die components and other components fitting inside a module, and by arranging several components in a single module. A stacked electronics package according to the invention consists of functional blocks or modules that are stacked on top of each other. Different product variations can be made using personalized blocks in a stacked package.

A module according to one embodiment of the invention consists of a carrier substrate having a recess in which components are attached. The recess is filled up with molding compound so that the connection pads of the components are exposed facing upwards. The wirings of a module that are connected to the connection pads are formed using inkjet printed conductive and dielectric materials. The module can be used as single module or as a stackable functional block to be stacked together with other functional blocks.

It is to be noted that the recess in the carrier substrate can comprise a through-hole on part or all of its area. In other words, the recess, which in some embodiments has a bottom, in other embodiments comprises or forms a through-hole without a bottom. In this case the components are placed in said through-hole at level with said carrier substrate before filling the through-hole with molding material. In exemplary embodiments of the invention the component(s) is/are attached to the side wall of said through-hole, by using adhesives or by force-fit.

With the invention the same carrier substrates can be used in several products, wherein only components and wirings inside of the blocks vary. Using inkjet printed wirings gives more flexibility to the manufacturing process. Design changes can be made easily. Printing of wires can be done dynamically, i.e. the design of wirings can be changed flexibly in an “on-the-fly” manner. The inkjet printing process minimizes the amount of waste.

The interconnection terminals at the bottom of an electronics package according to the invention enable an SMT compatible attachment to a printed wiring board (PWB). The terminals or pads also enable the stacking of multiple modules on top of each other, using different attachment methods as e.g. solder balls, coated polymer balls and conductive adhesives. The vertical interconnections are mainly located in the peripheral area, i.e. the carrier substrate outside of the recess area. However, with the invention the vertical interconnections can also be located in the center part of a module, i.e. in the inkjet printed area or the recess area, respectively.

Then the interconnection is made between bottom pads of the upper block, and the pads are formed using inkjet printed conductive material. The topmost stacked block can comprise components on top of it, but also the block(s) of other layer(s) can comprise components on top of them, provided these components comprise a height allowing them to be fitted into the space between stacked blocks.

If a stackable block is flipped the former bottom area now facing upwards can be used for example for antennas formed using methods to obtain high conductivities, e.g. conventional PWB manufacturing methods or different thin or thick film methods. Flipping the block in this manner allows using it as a kind of “lid” on top of a stacked package. In addition, modules can comprise shield planes providing electromagnetic shielding for radio frequency (RF) sensitive components.

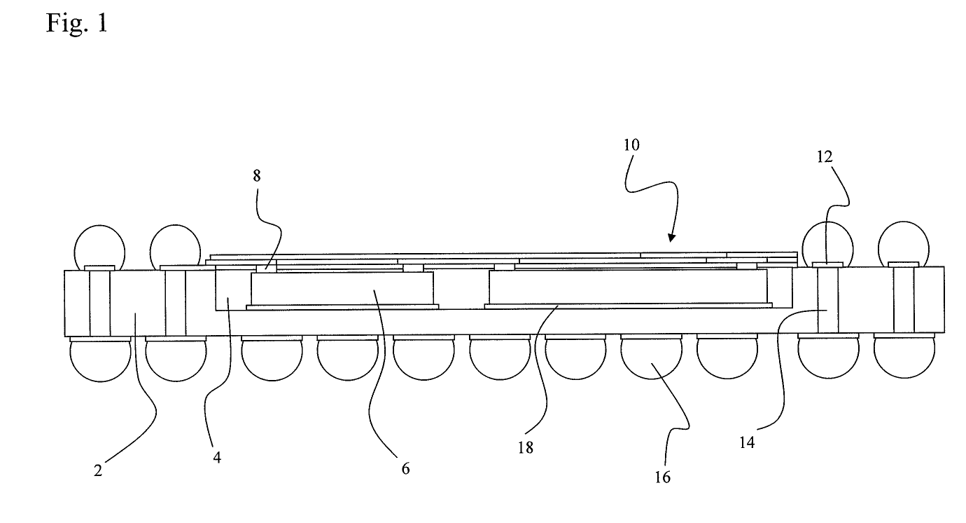

FIG. 1 illustrates an electronics package according to the invention. A carrier substrate 2 can be made like a conventional PWB or using other methods to form a rigid substrate. The carrier substrate 2 comprises a recess 4 and can contain multiple layers. Components 6 are attached to the bottom of recess 4, e.g. by an attachment, e.g. using a die attachment adhesive 18. Such components 6 can e.g. be bare dies of electronic components. The recess 4 is filled using a molding material, such that connection pads 8 of the components 6 are exposed, in this figure facing upwards.

Bumps 8 or a corresponding metallization provide a contact area for circuit layers to be applied. The application can be performed, according to the invention, using inkjet printing with conductive and dielectric inks. A circuit layer 10 comprising conductive and dielectric materials is applied on top of the package. Layer 10 can be a multi-layer forming printed wirings and dielectric layers, and provides conductive paths connecting the components 6 and forming an electronic circuit pattern.

Vertical interconnections 12 are provided to contact other function blocks that can be stacked on top of the shown module. Vias 14 are provided to enable connections across multiple stacked blocks. The vias can be made using microvias or plated-through-holes. On the bottom of the module an SMT compatible interconnection array of interconnections 16 is shown. By using standard compatible carrier substrates in connection with the SMT compatible interconnection an easy connection with other components is possible with a module of the invention.

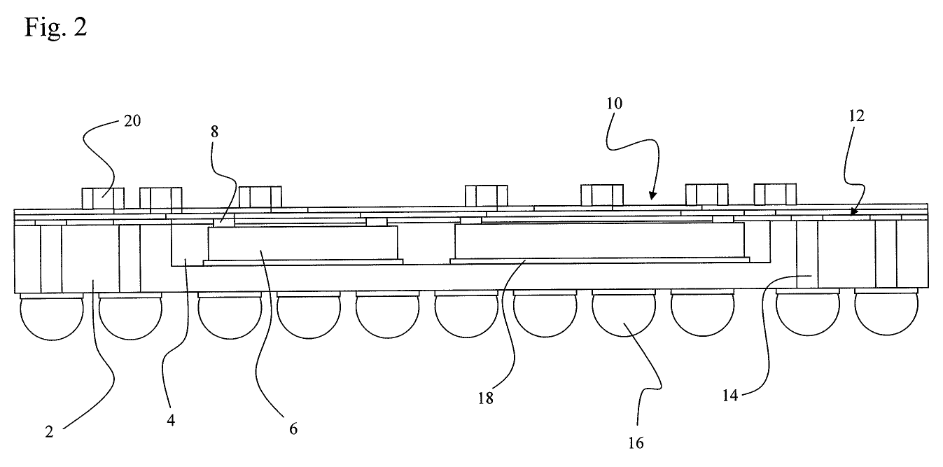

FIG. 2 shows another variation of a module of the invention with basically similar structure and components as in the embodiment of FIG. 1, so reference is also made to the description of FIG. 1. However, no interconnections are formed on the top here. Instead the circuit layer 10 extends over the whole area. On top of layer 10 additional electronic components 20 are located, e.g. standard surface mounted devices SMD or flip-chip components. This embodiment is particularly intended as a single module in a non-stacked arrangement, or as the topmost module of a multi-module stack.

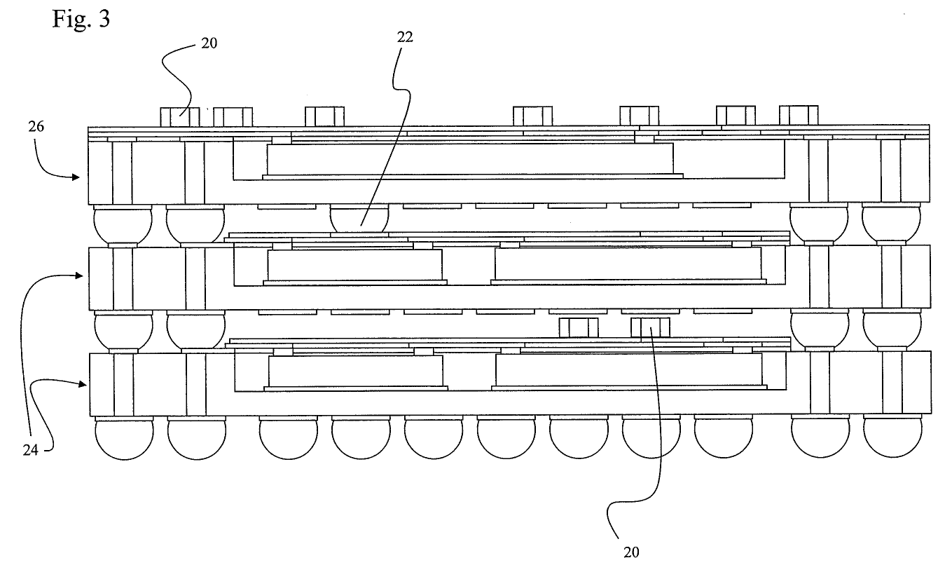

FIG. 3 shows a stacked arrangement according to an embodiment of the invention, in this case constituted by three stacked modules. The bottom and middle modules 24 can be implemented for example as in the embodiment of FIG. 1, whereas the topmost module 26 can be implemented as the embodiment of FIG. 2. A vertical interconnection 22 connects the upper module 24 with module 26, in the region of the respective cavities thereof. The inkjetted wirings are formed on the top of recess area and this enables the formation of pads for vertical interconnection on top of recess area. In the prior art it is not possible to form wirings and pads on top of the recess and die area, and thus to make vertical interconnections from any location in the module. The component placement restricted the locations. As can be seen here as well, it is possible to have top-mounted electronic components 20 not only on top of the whole stack, but also between modules within the stack, provided their height does not exceed the vertical space between the modules.

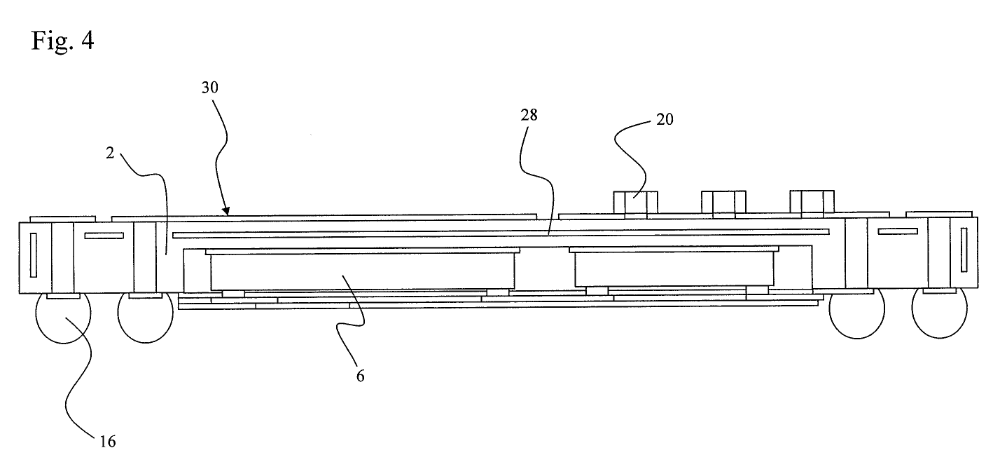

FIG. 4 shows another variation of a module of the invention. Compared to the embodiments in FIGS. 1-3 the module is shown head down here, i.e. the side of the carrier substrate having the recess is facing downwards. In this embodiment there are no interconnections on the side opposite the recess, that is, on top in this figure. The carrier substrate comprises an additional internal shielding layer 28 provided for electromagnetic shielding.

On the upper side of the carrier substrate 2 an antenna structure 30 is applied. This antenna structure 30 can e.g. be applied by inkjet printing using conductive ink. In the example shown here it is connected electrically to one of the vias, which in turn establishes an internal connection within the carrier substrate (i.e. not visible in this cross section) with the electronic component 6.

Electronic components 20 are located on top of the module, e.g. SMD or flip chip parts. The bottom connectors 16 can (this also applies to all other embodiments) be made using solder balls or conductive adhesives. A module according to this embodiment can e.g. be used as the topmost (or bottom, when oriented 180° turned) module of a multi-module stack, including the antenna structure (e.g. for use in a mobile phone or like) and the associated electromagnetic shielding layer.

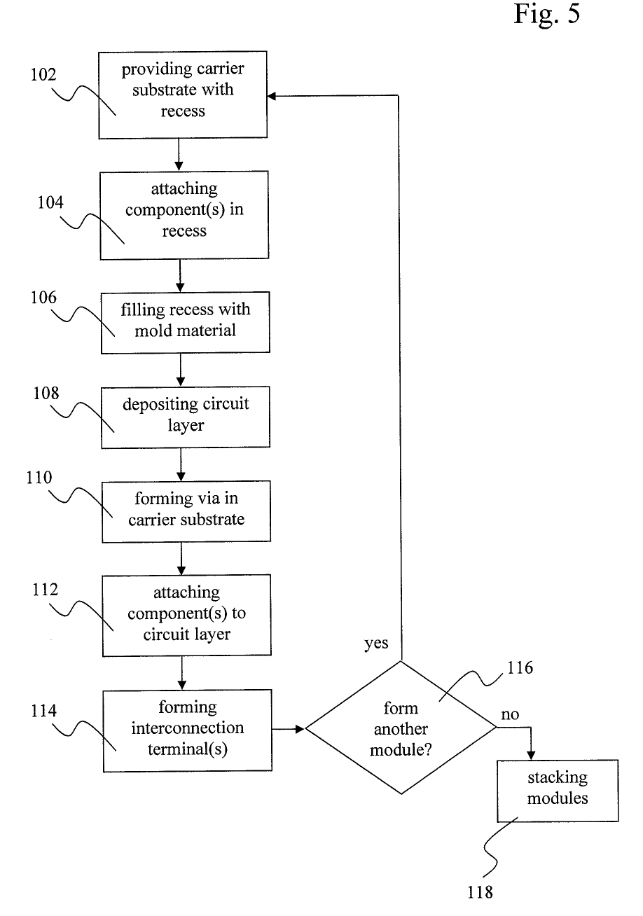

FIG. 5 shows steps of an exemplary embodiment of the method of the invention. In step 102 a carrier substrate is provided, the substrate comprising a recess. At least one electronic component is attached in the recess in step 104. This may include attaching the component(s) to the bottom of the recess, via a die attachment.

In step 106 the recess is filled with a suitable molding material, up to a height such that connection pads of the electronic components in the recess are exposed. A circuit layer is deposited in step 108, connected with the connection pads of the electronic components and forming an electrical circuit pattern. The circuit layer comprises both conductive as well as dielectric materials, to form conductive paths connecting electronic components. The circuit layer must not necessarily connect (only) components on the currently formed module, but can (either alternatively or additionally) be provided to connect with other modules and/or components that are not part of the module itself. This e.g. applies to stacked packages where more than one module is included.

In step 110 a via is formed in the carrier substrate. It is to be noted that this step is optional. It is mainly intended to provide vias connecting a plurality of vertically stacked modules, e.g. providing a conductive path from a bottom module to a top module in a stack.

Depending on the geometry of the formed module it is possible to perform optional step 112, wherein at least on electronic component is attached to the circuit layer. In case the formed module will be the topmost module of a stack this should usually not depend on any height restrictions. However, in case the current module is to be stacked between other modules, i.e. being an intermediate module, the height of the at least one component must be suitable to fit into the vertical space between the modules.

In step 114 at least one interconnection terminal is formed. This is mainly intended to provide an SMT compatible interconnection array allowing to connect the module of the invention with other (standard) components, e.g. a printed wiring board, using standard processes, e.g. soldering. It may however also serve to provide connections with other modules that are stacked together with the current module. In this manner it is e.g. possible to have an SMT compatible interconnection array on the bottom of the module, and some proprietary interconnections on top of the module for connection with other non-standard modules.

In step 116 the process branches. Steps 102 to 114 for forming another module can be repeated, in which case the process returns from step 116 to step 102 again. When all required modules are formed, step 116 continues to step 118. In step 118 all formed modules are stacked and connected suitably, using the provided interconnections terminals. It should be understood that all references to “top”, “upper”, “bottom” and the like occurring throughout this description are dependent on the actual orientation of a device they refer to and are thus only provided to improve the understanding of the figures etc. For the invention it is apparently irrelevant how a module is oriented, although a specific orientation may be required for certain steps as e.g. inkjet printing.

To summarize, stacked modules that are made possible by the invention are small compared to conventional ways of assembling components. This also enables smaller and lighter products, with more functionality. Another advantage relates to modularity, because in the invention the same carrier can be used in several products which allows to lower costs. Using inkjet printed wirings provides more flexibility to the manufacturing process. In this manner design changes can be made easily. Inkjet printing process additionally minimizes the amount of waste materials. Modules according to embodiments of the invention are SMT compatible and can be attached e.g. using conventional lead-free reflow soldering processes. Although the fabrication process described above can be performed manually, either in whole or in part, the fabrication process can be performed in an automated manner under control of a computer which, in turn, operates in accordance with computer program instructions stored by a computer-readable medium.

While the foregoing specification is provided to draw attention to those features of the invention believed to be of particular importance it should be understood that protection is claimed with respect to any patentable feature or combination of features referred to and/or shown in the drawings, whether or not particular emphasis has been put thereon. It should be appreciated that those skilled in the art, upon consideration of the present disclosure, may make modifications and/or improvements on the method and device hereof and yet remain within the scope and spirit of the invention as set forth in the appended claims.

1. Method for manufacturing an electronics package, comprising:
forming at least one module block, comprising
providing a carrier substrate comprising a recess;
placing at least one electronic component die in said recess;
filling said recess with a molding material; and
depositing a circuit layer connected with said at least one component die.

2. Method according to claim 1, wherein said recess comprises a through-hole, and wherein said placing step comprises placing said at least one electronic component in said through-hole at level with said carrier substrate.

3. Method according to claim 1, wherein said circuit layer comprises conductive and dielectric materials.

4. Method according to claim 1, wherein said at least one component die is attached to the bottom of said recess.

5. Method according to claim 1, further comprising:
forming at least one via in said carrier substrate.

6. Method according to claim 1, further comprising:
attaching at least one electronic component to said circuit pattern.

7. Method according to claim 1, wherein said carrier substrate is provided with an internal wiring, and wherein said circuit layer is deposited such that it also connects said internal wiring.

8. Method according to claim 1, further comprising:
forming at least one interconnection terminal.

9. Method according to claim 8, wherein said at least one interconnection terminal is formed in the area of said recess.

10. Method according to claim 8, wherein at least two module blocks are formed, the method further comprising:
stacking said at least two module blocks on top of each other, wherein said at least one interconnection terminal electrically connects said at least two module blocks.

11. Method according to claim 5, further comprising:
depositing a second circuit layer on said carrier substrate on the side opposite to said recess, said second circuit structure being connected with said at least one via.

12. Method according to claim 1, wherein said carrier substrate is provided with an electromagnetic shielding layer.

13. Computer-readable medium storing instructions for instructing a computer to perform the steps of claim 1 when run on said computer.

14. Electronics package, comprising:
a carrier substrate comprising a recess;
at least one electronic component die placed in said recess;
a molding material filling said recess; and
a circuit layer connected with said at least one component die.

15. Electronics package according to claim 14, wherein said recess comprises a through-hole, and wherein said at least one electronic component is placed in said through-hole at level with said carrier substrate.

16. Electronics package according to claim 14, wherein said circuit layer comprises conductive and dielectric materials.

17. Electronics package according to claim 14, wherein said at least one component die is attached to the bottom of said recess.

18. Electronics package according to claim 14, further comprising:
at least one via in said carrier substrate.

19. Electronics package according to claim 14, further comprising:
at least one electronic component attached to said circuit pattern.

20. Electronics package according to claim 14, wherein said carrier substrate further comprises an internal wiring, and wherein said circuit layer connects with said internal wiring.

21. Electronics package according to claim 14, further comprising:
at least one interconnection terminal.

22. Electronics package according to claim 21, wherein said at least one interconnection terminal is located in the area of said recess.

23. Electronics package according to claim 21, comprising at least two module blocks stacked on top of each other, wherein said at least one interconnection terminal electrically connects said at least two module blocks.

24. Method according to claim 18, further comprising:
a second circuit layer on said carrier substrate on the side opposite to said recess, said second circuit structure being connected with said at least one via.

25. Electronics package according to claim 14, further comprising:
an electromagnetic shielding layer.
